(19) United States
(12) Patent Application Publication
(10) Pub. No.: US 2023/0207667 A1
(43) Pub. Date: Jun. 29, 2023

(54) ULTRA-DENSE THREE-DIMENSIONAL TRANSISTOR DESIGN

(71) Applicant: Tokyo Electron Limited, Tokyo (JP)

(72) Inventors: H. Jim FULFORD, Marianna, FL (US); Mark I. GARDNER, Cedar Creek, TX (US); Partha MUKHOPADHYAY, Oviedo, FL (US)

(73) Assignee: Tokyo Electron Limited, Tokyo (JP)

(21) Appl. No.: 17/952,552

(22) Filed: Sep. 26, 2022

Related U.S. Application Data
(60) Provisional application No. 63/294,440, filed on Dec. 29, 2021.

(51) Int. Cl. H01L 29/66; H01L 29/06; H01L 29/423; H01L 29/417; H01L 23/528; H01L 29/786

(52) U.S. Cl. CPC H01L 29/66795; H01L 29/0665; H01L 29/4236; H01L 29/41725; H01L 23/528; H01L 29/78696

(57) ABSTRACT

A semiconductor device includes a substrate, a first wiring layer over the substrate, and a first array of transistor pairs extending over the first wiring layer. Cross sections of each transistor pair cut through the first array. The cross sections of each transistor pair have a similar structure. Each transistor pair includes a mandrel having two opposite sidewalls that are perpendicular to the substrate and extending along a direction of the first array of transistor pairs. Each transistor pair includes two transistors symmetrically disposed over the two opposite sidewalls of the respective mandrel.

### INCORPORATION BY REFERENCE

This present disclosure claims the benefit of U.S. Provisional Application No. 63/294,440, “Ultra-Dense 3D Transistor Design with Dielectric Separation and Metal First Method using Semiconductive Oxide Integration,” filed on Dec. 29, 2021, which is incorporated herein by reference in its entirety.

### TECHNICAL FIELD

The present disclosure relates to microelectronic devices (including semiconductor devices, transistors, and integrated circuits) and methods of microfabrication.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single-digit nanometer semiconductor device fabrication nodes. Semiconductor device fabricators have expressed a desire for three-dimensional (3D) semiconductor circuits in which transistors are stacked on top of each other.

### SUMMARY

Aspects of the disclosure provide a method for fabricating a semiconductor device. The method can include forming a first wiring layer over a substrate; forming mandrels over the first wiring layer, each mandrel having two opposite sidewalls that are perpendicular to the substrate and extend over the substrate; forming a channel layer on each sidewall of each mandrel, the channel layer being in electrical contact with the first wiring layer; forming a gate dielectric layer over the channel layer on each sidewall of each mandrel; forming a gate electrode layer over the gate dielectric layer formed over the channel layer on each sidewall of each mandrel; and forming, corresponding to each mandrel, multiple trenches, the multiple trenches crossing the respective mandrel, the channel layer on each sidewall of the respective mandrel, the gate dielectric layer over the channel layer on each sidewall of the respective mandrel, and the gate electrode layer over the gate dielectric layer formed over the channel layer on each sidewall of the respective mandrel, resulting in a first array of transistor pairs corresponding to each mandrel.

In an embodiment, the first wiring layer includes pairs of source/drain (S/D) contact structures. The S/D contact structures in each pair extend in a same direction as the mandrels. Each mandrel corresponds to a pair of S/D contact structures among the pairs of the S/D contact structures. Each mandrel is positioned above a region extending between the two S/D contact structures of the respective pair of the S/D contact structures such that the two S/D contact structures are positioned at two sides of the respective mandrel, respectively. The channel layer on each sidewall of each mandrel is in electrical contact with a respective S/D contact structure of the respective pair of S/D contact structures in the first wiring layer. In an example, the multiple trenches corresponding to each mandrel cross the respective pair of S/D contact structures.

In an embodiment, each transistor pair has two transistors disposed on opposite sidewalls of a portion of the respective mandrel. The portion of the respective mandrel results from the multiple trenches crossing the respective mandrel. In an embodiment, each transistor has a channel perpendicular to the substrate and a gate over the channel. The channel is a portion of the channel layer resulting from the multiple trenches crossing the respective mandrel. The gate is a combination of a portion of the gate dielectric layer and a portion of the gate electrode layer resulting from the multiple trenches crossing the respective mandrel.

In an embodiment, a second wiring layer is formed above the channels. The channels are electrically connected to the first wiring layer providing a first S/D contact structure and the second wiring layer through a second S/D contact structure. In an embodiment, the gate is connected to the first wiring layer or the second wiring layer. In an example, second arrays of transistor pairs are formed over the second wiring layer in a similar way as forming the first arrays of transistor pairs over the first wiring layers such that the second arrays of transistor pairs are stacked over the first arrays of transistor pairs. In an example, the second wiring layer includes multiple metal layers. In an example, the channel is a nanosheet channel.

In some embodiments, the first wiring layer includes multiple metal layers. In an example, the transistor pairs are embedded in a low-k dielectric material. In an example, the channel includes one of a semiconductive oxide and a semiconductive 2D material.

In an example, the method further includes, after forming the channel layer on each sidewall of each mandrel, forming a dielectric layer over the first wiring layer, followed by the forming of the gate dielectric layer over the channel layer on each sidewall of each mandrel, such that the dielectric layer insulates the gate dielectric layer and the gate electrode layer from the first wiring layer under the dielectric layer. In an embodiment, the channel includes one of the following materials: In2O3, SnO2, InGaZnO, ZnO, and SnO.

Aspects of the disclosure provide a semiconductor device. The semiconductor device includes a substrate, a first wiring layer over the substrate, and a first array of transistor pairs extending over the first wiring layer. Cross sections of each transistor pair cut through the first array. The cross sections of each transistor pair have a similar structure. Each transistor pair includes a mandrel having two opposite sidewalls that are perpendicular to the substrate and extending along a direction of the first array of transistor pairs. Each transistor pair includes two transistors symmetrically disposed over the two opposite sidewalls of the respective mandrel.

In an embodiment, each of the two transistors has a channel over one of the two opposite sidewalls of the respective mandrel, a gate dielectric over the channel, and a gate electrode over the gate dielectric. In an embodiment, the semiconductor device includes a second wiring layer in parallel with the first wiring layer and above the first array of transistor pairs. The channel of each of the two transistors is in electrical connection with the first wiring layer providing a first source/drain (S/D) contact structure to the channel and with the second wiring layer through a second S/D contact structure.

In an embodiment, the semiconductor device includes a transistor layer stacked over the second wiring layer. The transistor layer includes a second array of transistor pairs each having a cross-section having a similar structure as that of each of the first array of transistor pairs. Channels of the second array of transistors are in electrical connection with S/D contact structures provided in the second wiring layer. In an embodiment, the first wiring layer and the second wiring layer each include one or more metal layers, and the first array of transistor pairs and the second array of transistor pairs extend in a same direction or different directions.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements. It is noted that, in accordance with the standard practice in the industry, various features are not drawn to scale. In fact, the dimensions of the various features may be arbitrarily increased or reduced for clarity of discussion.

FIGS. 1-11 show an example fabrication process flow according to embodiments of the disclosure.

FIG. 12 shows a perspective view of the intermediate structure shown in FIG. 11 with the dielectric layer 31 being removed.

FIG. 13 shows a fabrication process 1300 according to embodiments of the disclosure.

### DETAILED DESCRIPTION OF EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Moreover, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Three-dimensional (3D) integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

Techniques herein include methods and designs for microfabrication of semiconductor devices. Techniques herein provide high-performance channels using conductive oxides or oxides that are semiconductive. Embodiments include metal first integration. Embodiments include dielectric separation along with metal first approach allows ultra-dense design for fabricating transistors with semiconductive oxide layers for the device semiconductor regions. A pre-aligned mask is provided for easy etching trench to fabricate devices. The alignment offset of three different masks has no effect on device performance. Using vertical nanosheets allows for stacking N devices tall. Techniques herein do not require epitaxially grown silicon. A benefit of such techniques is that relatively few process steps are needed to produce high-performance CMOS devices.

Techniques provided herein may use alternative semiconductors in the microfabrication of semiconductor devices. Such semiconductors herein can be alternatives to silicon, germanium, gallium arsenide, and other commonly used semiconductors.

Semiconductors and structures herein can include semiconductive oxides, semiconductive 2D materials, and semiconductive materials. This includes semiconductors (materials) that can be formed at relatively low temperatures and without epitaxy.

Semiconductive materials herein may have properties similar to elemental semiconductor materials, and can be used to fabricate vertical stacks or planes of transistors. Note that given transistors within the vertical stacks can have channels with horizontal or vertical orientation relative to a working surface of the substrate. Certain materials, when combined with oxygen, may form new materials that exhibit semiconductor properties. For example, these semiconductor materials can turn “off” with low off-state leakage current or can become highly conductive under certain circumstances. In other words, such materials have an electrical conductivity value falling between an electrical conductor and an electrical insulator.

Some examples of N-type semiconductive materials for channels include In2O3, SnO2, InGaZnO, and ZnO. One example of a P-type semiconductive material for channels is SnO. Thus, a “semiconductive oxide” herein is an oxygen-containing material having semiconductor properties.

Additionally, or alternatively, materials and channels may comprise a two-dimensional (2D) material. Some example 2D materials for use in forming a channel include, but are not limited to, WS2, WSe2, WTe2, MoS2, MoSe2, MoTe2, HfS2, ZrS2, TiS2, GaSe, InSe, phosphorene, and other similar materials. A “semiconductive 2D material” herein is a 2D material with semiconductor properties. The 2D materials described herein may be deposited by, for example, an atomic layer deposition (ALD) process and may be 5-15 angstroms thick, the thinness lending to their name-2D material. Other deposition techniques may also be used, including, but not limited to, chemical vapor deposition (CVD), physical vapor deposition (PVD), and plasma-enhanced deposition techniques.

The materials may be annealed during or after the device formation process to recrystallize or grow the crystals and thereby improve electrical characteristics. Thus forming a semiconductive material can include deposition and annealing. A “semiconductive material” herein can be any material with semiconductor properties. Such materials can include elements or compounds normally associated with dielectrics. Such materials can include compounds formed without requiring a seed layer, and can be formed at temperatures lower than about 500-600 degrees Celsius.

Semiconductive materials that can be formed/deposited on a substrate without requiring a seed layer and/or at processing temperatures lower than 600 degrees Celsius are beneficial in forming vertical stacks or planes of transistors (3D transistors). In contrast, semiconductors used to make conventional semiconductor devices are often formed by epitaxy, which requires a seed layer for growth. Requiring a seed layer can mean a need to uncover a particular material on a substrate that might be covered by many layers and structures. As can be appreciated, without needing to integrate access to a seed layer into a given fabrication flow, a semiconductive material can be easily formed over an existing plane of transistors to create an additional plane of transistors.

Moreover, formation of conventional semiconductors can require high-temperature deposition and annealing (greater than about 600 degree Celsius). After initial high-temperature processing, additional materials are added that may not tolerate high-temperature processing. This means that if a first plane of transistors is formed, adding a second plane of transistors that needs high-temperature processing can damage the first plane of transistors, leading to device failure. Accordingly, semiconductor materials that can be formed at less than 600 degrees Celsius are desirable. Without requiring a seed layer or high-temperature processing, semiconductive materials herein can be formed on many different surfaces, easily integrate with various fabrication flows, and help enable vertical stacking of transistors.

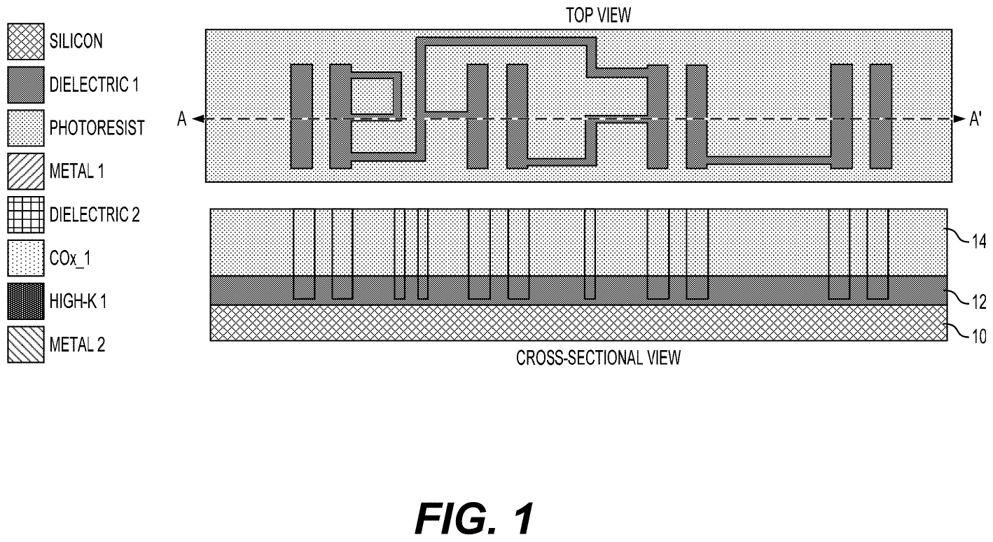

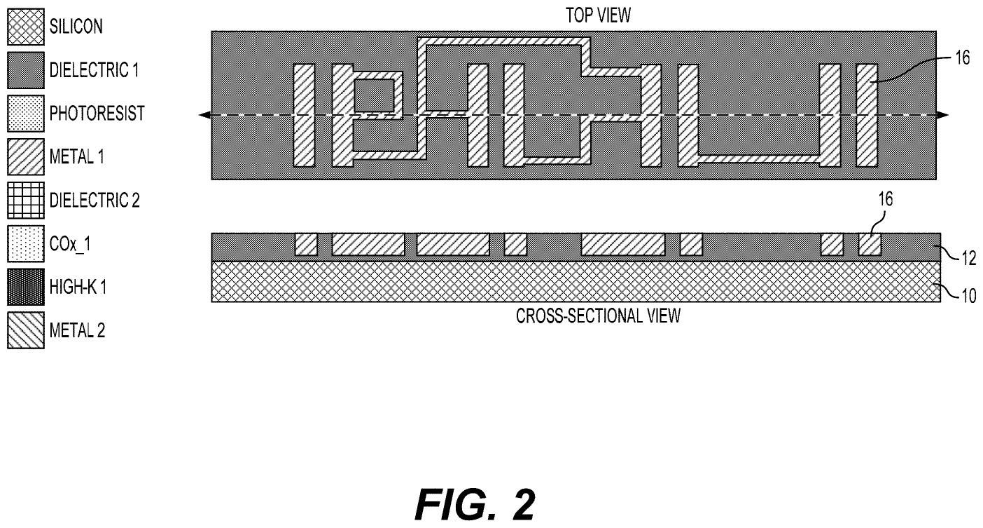

An example fabrication process flow is described with reference to the figures from FIG. 1 to FIG. 11. Each figure shows a top view (the upper one) and a cross-sectional view (the lower one) of an intermediate structure corresponding to an intermediate stage of the process flow for fabricating 3D transistors. A cut line A-A′ in FIG. 1 shows the position of the cutting plane for the respective cross-sectional view in FIG. 1. For other figures from FIG. 2 to FIG. 11, the cutting plane for the respective cross-sectional view is taken at the same position as in FIG. 1 over the respective top view and is not shown in the respective figure.

In FIG. 1, a dielectric layer 12 (shown with the pattern of Dielectric 1) is formed on a substrate 10 (shown with the pattern of Silicon). A photoresist layer 14 (shown with the pattern of Photoresist) is formed on the dielectric layer 12. Using a mask of a metal layer (referred to as M1 mask), the photoresist layer 14 can be patterned. Based on the patterned photoresist layer 14, the dielectric layer 12 is etched halfway (partially) for deposition of the metal layer. Etching partially into the dielectric layer 12 helps keep isolation between the substrate 10 (that may contain conductive or semiconductive materials) and the metal layer.

The substrate 10 may include silicon. The substrate 10 may alternatively be made of some other suitable elementary semiconductor, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide. Alternatively, the substrate may include a non-semiconductor material. In an embodiment, the substrate includes one or more material layers (e.g., insulating, conductive, semiconductive, etc.) formed thereon.

The dielectric layer 12 can be formed by depositing a dielectric material over the substrate 10. In an example, the dielectric material includes silicon dioxide or the like. In an example, the dielectric material includes a low-k dielectric material, such as Fluorine-doped silicon dioxide, organosilicate glass or osg (carbon-doped oxide or cdo), porous silicon dioxide, porous organosilicate glass (carbon-doped oxide), spin-on organic polymeric dielectrics, spin-on silicon based polymeric dielectric, or the like. In an example, the dielectric material includes high-k dielectrics.

In FIG. 2, after stripping the photoresist layer 14, a conductive material (e.g., a metal) can be deposited to fill the trenches formed in the dielectric layer 12 in the process of FIG. 1. The overburden of the conductive material can be removed, resulting in the metal layer, now labeled with the numeral 16 (shown with the pattern of Metal 1). In an example, a chemical-mechanical polishing (CMP) is applied to remove the overburden. The metal layer 16 can include aluminum, copper, tungsten, or the like. Generally, any suitable metal or non-metal conductive materials can be used in place of the metal layer 16. In such a case, the metal layer 16 may be referred to as a conductive layer to broadly cover various conductive materials in various applications.

Further, instead of one metal layer 16 being fabricated in the FIG. 2 example, multiple layers of routing wires (e.g., multiple metal layers) and interconnects between neighboring layers can be formed in other examples. Generally, any number of conductive layers can be used to connect transistors formed above.

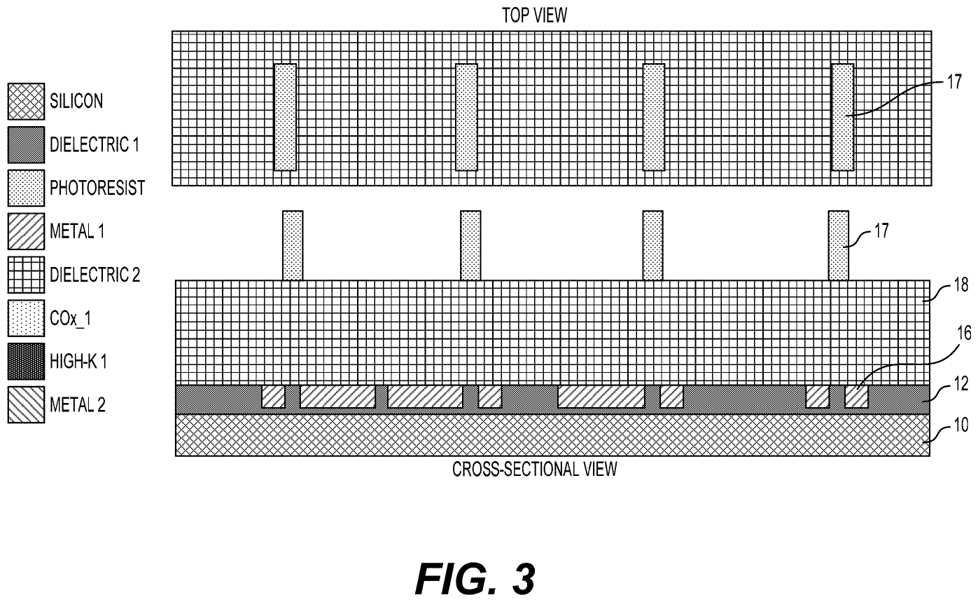

In FIG. 3, another dielectric layer 18 (shown with the pattern of Dielectric 2) can be formed over the metal layer 16 and the dielectric layer 12. Another layer of photoresist can be formed to cover the top surface of the dielectric layer 18. Using a mask (e.g., a nanosheet mask), the layer of photoresist can be patterned to form the etch mask 17 (shown with the pattern of Photoresist).

The dielectric layer 18 can be formed by depositing a dielectric material. In an example, the dielectric material includes silicon dioxide or the like. In an example, the dielectric material includes a low-k dielectric material, such as Fluorine-doped silicon dioxide, organosilicate glass or osg (carbon-doped oxide or cdo), porous silicon dioxide, porous organosilicate glass (carbon-doped oxide), spin-on organic polymeric dielectrics, spin-on silicon based polymeric dielectric, or the like. In an example, the dielectric material includes high-k dielectrics. As shown in later stages, the dielectric layer 18 is further shaped to form mandrels which each function as an insulator between a pair of transistors.

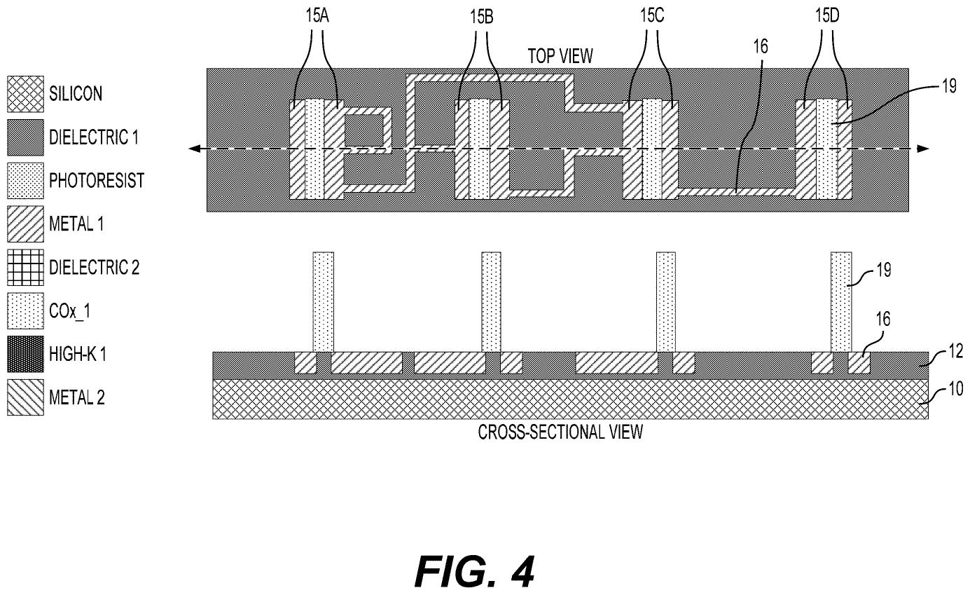

In FIG. 4, the dielectric layer 18 is etched down based on the etch mask 17 to form dielectric pillars (or pillar structures) 19. A directional (anisotropic) etching process can be applied to form the dielectric pillars. The etch mask 17 can then be stripped. It is noted that the dielectric pillars 19 need not be aligned to the metal layer 16 perfectly. The alignment has a good margin of allowable misalignment without affecting the further process and the device performance. This advantage can simplify the fabrication process and lower the fabrication cost.

The profile of the dielectric pillars 19 is shown to be rectangular in the top view of FIG. 4. However, in other examples, the top-view profile of the dielectric pillars can have a shape other than a rectangular shape, such as a capsule shape.

As shown, the metal layer 16 includes pairs of source/drain (S/D) contact structures 15a-15d. Each pillar structure 19 corresponds to a pair of S/D contact structures among the pairs of the S/D contact structures 15a-15b. Each pillar structure 19 is positioned above a region extending between the two S/D contact structures of the respective pair of the S/D contact structures. Accordingly, the two S/D contact structures are positioned at two sides of the respective pillar structure 19, respectively.

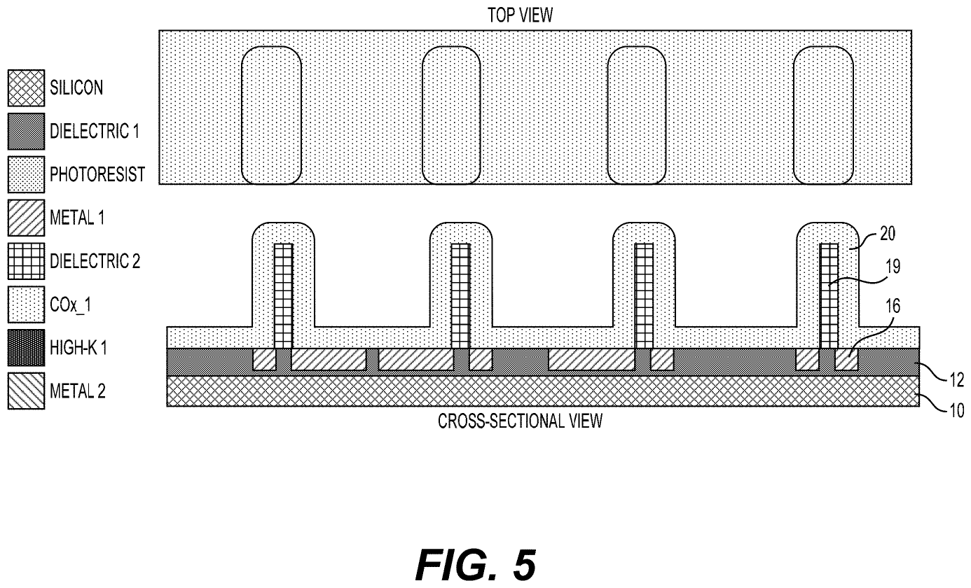

In FIG. 5, a channel material layer 20 (shown with the pattern of COx_1) can be conformally formed over the intermediate structure shown in FIG. 4. The channel material layer 20 touches the metal layer 16. The channel material layer 20 also covers the surface of the pillar structures 19, including the top side and the vertical sides of each dielectric pillar 19. In an example, an atomic layer deposition (ALD) method is applied to form the channel material layer 20. The channel material layer 20 can be formed as a nanosheet. In other examples, other types of deposition methods can be used, such as chemical vapor deposition (CVD), physical vapor deposition (PVD), or the like.

The channel material layer 20 includes a semiconductive material. In an example, the channel material layer 20 includes a semiconductive oxide. In an example, the channel material layer 20 includes a 2D material. In an example, the channel material layer 20 can include a conventional semiconductive material, such as silicon, germanium, gallium arsenide, and the like. In some examples, the channel material layer 20 can include a material or a combination of materials that can include compounds formed without requiring a seed layer, and thus can be formed at temperatures lower than, for example, about 500-600 degrees Celsius.

As shown, the channel material layer 20 (later becoming transistor channels) naturally touches the metal layer 16 (later becoming source/drain (S/D) contacts), thus, waving the misalignment effects greatly.

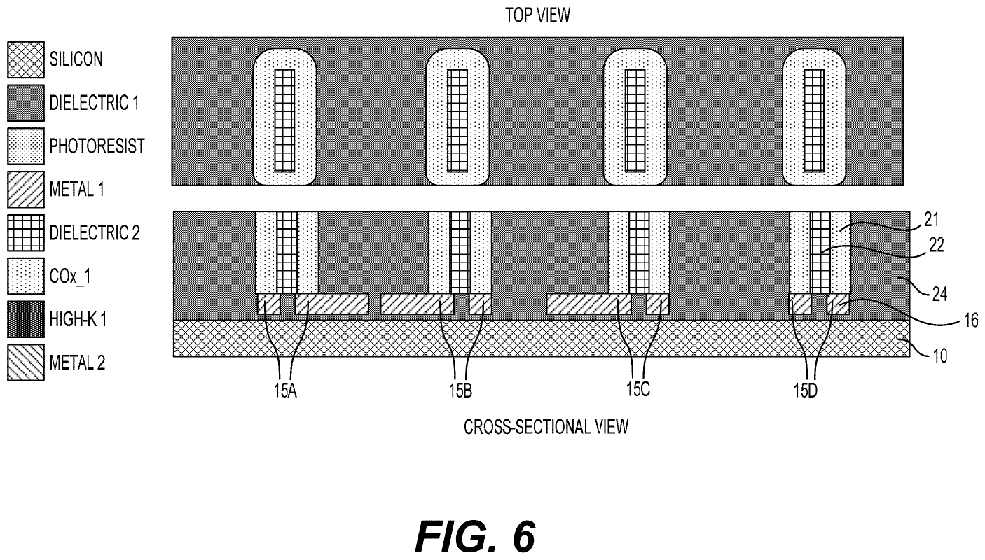

In FIG. 6, the channel material layer 20 is directionally etched down. As a result, the channel materials on the sidewalls of the dielectric pillars 19 are maintained, while the channel materials above the metal layer 16 is removed to expose the top surface of the metal layer 16. The channel materials on the top of the dielectric pillars 19 may also be removed. Then, a dielectric material (shown with the pattern of Dielectric 1) is deposited over the substrate 10 to embed the structures over the substrate 10. In the FIG. 6 example, the newly deposited dielectric material is in contact with the dielectric layer 12, resulting in a dielectric layer 24.

Next, a CMP is applied to chop off the top portions of the dielectric pillars 19 and the top portions of the channel materials remaining on the sidewalls of the dielectric pillars 19. After the CMP, the remaining portions of the pillar structures 19 are referred to as dielectric mandrels (or mandrels) 22; the remaining channel materials on the sidewalls of the mandrels are referred to as channel regions 21 (or channel layers).

As a result of the series of operations of the FIG. 6, four pairs of channel regions 21 are created. Each pair of channel regions 21 has a mandrel 22 serving as an insulator to separate the respective channel regions 21. Also, each channel region 21 is naturally in contact with the metal structures below. The channel region 21 on each sidewall of each mandrel 22 is in electrical contact with a respective S/D contact structure of the respective pair of S/D contact structures 15a-15d of the metal layer 16.

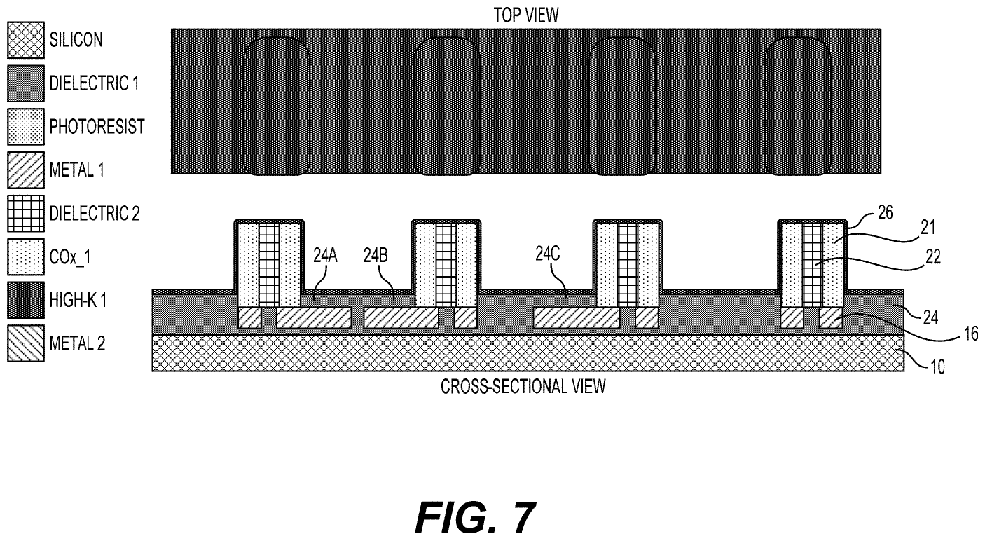

In FIG. 7, a selective etch is applied to etch down the dielectric layer 24 to expose the sidewalls of the channel regions 21. Then, a dielectric layer 26 (shown with the pattern of High-k1) is formed conformally over the intermediate structure resulting from FIG. 6. In an example, an ALD deposition is applied to form the dielectric layer 26. In other examples, other types of deposition methods may be employed, such as CVD, PVD, or the like. The dielectric layer 26 can include any materials suitable for the function of a gate dielectric structure, such as silicon dioxide, high-k dielectrics, low-k dielectrics, and the like, depending on the particular application.

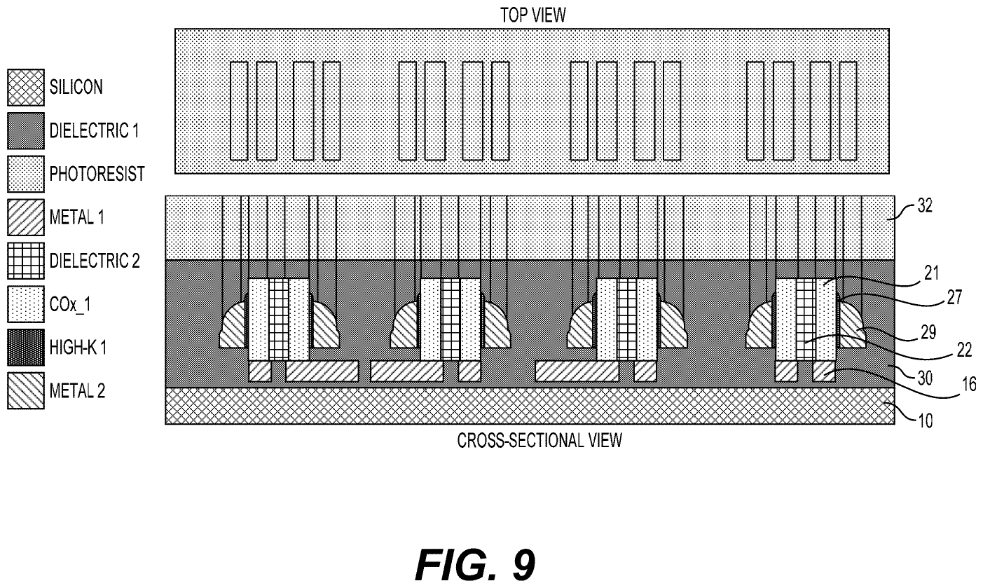

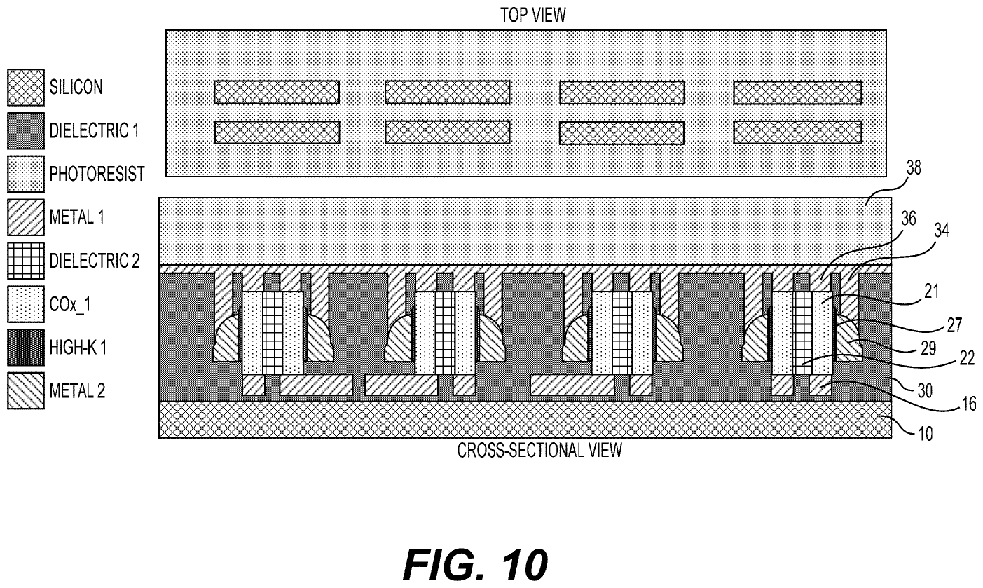

As shown in a later stage of FIG. 9 or FIG. 10, the dielectric layers 24a-24c between the dielectric layer 26 and the metal layer 16 function as insulators to isolate transistor gate structures from the metal layer 16 (that provides S/D contact structures).

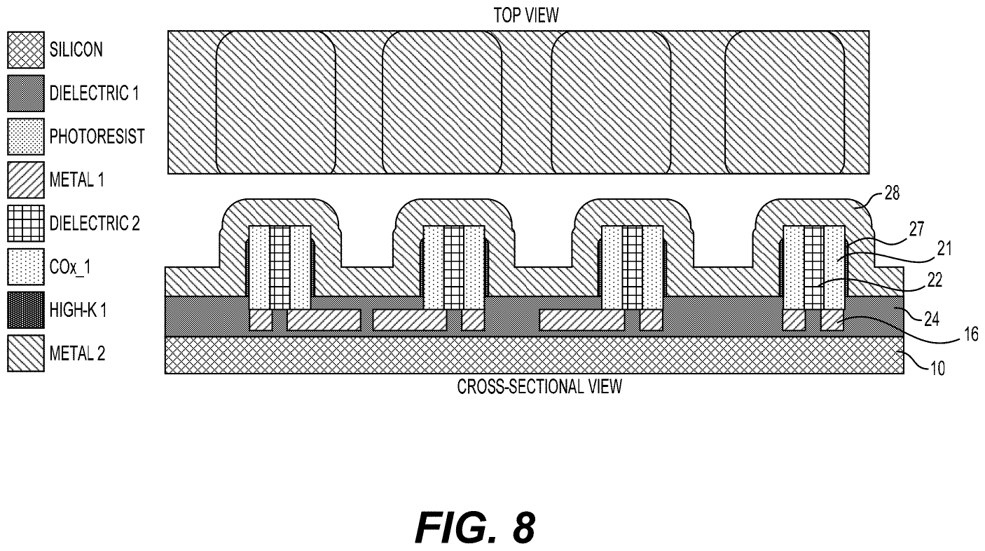

In FIG. 8, a directional etch is applied to remove portions of the dielectric layer 26 from the top surface of the dielectric layer 24 and the top surface of the mandrels 22 and the channel regions 21. The portions of the dielectric layer 26 remaining on the sidewalls of the channel regions 21 are referred to as gate dielectric layers 27.

Then, a gate material layer 28 (shown with the pattern of Metal 2) is formed conformally to cover the structures over the substrate 10. In an example, an ALD deposition is applied to form the gate material layer 28. In other examples, other types of deposition methods are employed to form the gate material layer 28. In an example, the gate material layer 28 can include one or more metals or non-metals suitable for the function of a gate electrode. In some examples, the gate material layer 28 includes polysilicon, a silicide material, metal composites (such as WN, TiN, or TaN), and the like.

In FIG. 9, a top-down directional etch can be applied to the gate material layer 28 to clear the top part thereof and to remove the short connections between the neighboring devices. The remaining part of the gate material layer 28 is referred to as gate electrode layers 29 in FIG. 9. Next, a dielectric layer (shown with the pattern of Dielectric 1) can be deposited to embed the structures over the substrate 10. The newly formed dielectric layer and the dielectric layer 24 are shown as the dielectric layer 30 in FIG. 9.

Next, a photoresist layer 32 (shown with the pattern of Photoresist) is formed over the dielectric layer 30 and patterned with a metal layer mask (referred to as M2 mask). Then the dielectric layer 30 is etched based on the patterned photoresist layer 32 with an etch stop on upper surfaces of the channel regions 21 and the upper surfaces of the gate electrode layers 29. As a result, trenches are formed above each channel region 21 and each gate electrode layer 29. Gate connections (or contacts) and channel connections (or contacts) can be formed within the trenches later.

As illustrated, the M2 mask pattern contains patterns of the gate connections (to the gate electrode layers 29) and the channel connections (to the channel regions 21). The alignment of the M2 mask has a good margin of allowable misalignment without affecting the further process and the device performance. This advantage can simplify the fabrication process and lower the fabrication cost.

In FIG. 10, the photoresist layer 32 in FIG. 9 is removed. No CMP is applied to the dielectric layer 30 at the current stage. A conductive material (shown with the pattern of Metal 1) is deposited to fill the trenches to form channel interconnections (or contacts) 36 and gate interconnections (or contacts) 34. The conductive material can include one or more metal or non-metal materials. In an example, the conductive material for forming the interconnections 34 and 36 includes the same material(s) as that of the metal layer 16.

Next, no CMP is applied to the conductive material forming the interconnections 34 and 36, and a lithography process with a separation mask is applied to chop continuous “bars”. Specifically, a photoresist layer 38 (shown with the pattern of Photoresist) is formed over the conductive material forming the interconnections 34 and 36. The photoresist layer 38 is then patterned with the separation mask. Then, a directional etch is performed based on the patterned photoresist layer 38 to chop the bars all the way to the substrate 10.

There are four bars in FIG. 10. Each bar corresponds to a mandrel 22. Each bar includes the respective mandrel 22, the pair of channel regions 21 attached to the sidewalls of the respective mandrel 22, the pair of gate dielectric layers 27 attached to the sidewalls of the respective channel regions 21, and the pair of gate electrode layers 29 attached to the respective gate electrode layers. By the directional etch with the pattern of the separation mask, each bar is chopped into three separate slices, resulting in trenches between the slices. Also, by the directional etch with the pattern of the separation mask, the pairs of S/D contact structures 15a-15d of the metal layer 16 are chopped into separate S/D contact structures each corresponding to a transistor-pair slice.

Each slice includes a pair of back-to-back arranged transistors (transistor pair) and can thus be referred to as a transistor-pair slice. Each such transistor includes a portion of the channel region 21, a portion of the gate dielectric layer 27, and a portion of the gate electrode layer 29, which, respectively, form a channel, a gate dielectric, and a gate electrode of the respective transistor. A combination of the gate dielectric and the gate electrode forms a gate of the respective transistor. In each transistor-pair slice, each transistor pair has two transistors disposed on opposite sidewalls of a portion of the respective mandrel 22. The portion of the respective mandrel 22 results from the multiple trenches crossing the respective mandrel 22.

For each transistor slice, a portion of the channel interconnection 36 (resulting from the chopping of the bar) functions as an S/D contact structure for the respective channel (transistor channel); and a portion of the gate interconnection 34 (resulting from the chopping of the bar) functions as a gate contact structure for the respective gate (transistor gate). While the gates of the transistors in FIG. 10 are shown to be connected to an upper metal layer (formed in a later stage), the gates of transistors in FIG. 10 can be connected to the bottom metal layer 16 in other examples.

The alignment of the separation mask has a good margin of allowable misalignment without affecting the further process and the device performance. This advantage can simplify the fabrication process and lower the fabrication cost.

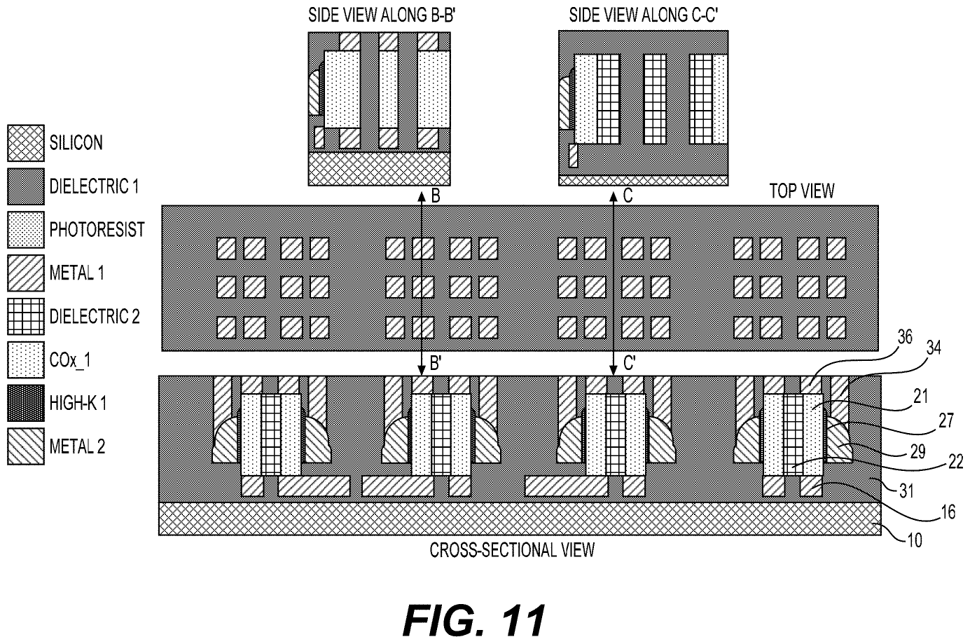

In FIG. 11, the photoresist layer 38 in FIG. 10 is stripped. A dielectric material is deposited to fill the trenches between the transistor-pair slices. The filled-in dielectric material functions as an insulator to isolate the transistors of neighboring transistor-pair slices. The newly formed dielectric material (shown with the pattern of Dielectric 1) and the dielectric layer 30 together are labeled as a dielectric layer 31 in FIG. 11. A CMP can be applied from top to the conductive material forming the interconnections 34 and 36 and to the dielectric layer 31. As a result, the top surfaces of the interconnections 34 and 36 can be exposed. In a later stage, one or more metal layers (and interconnections (e.g., vias) between neighboring metal layers) can be formed above the interconnections 34 and 36 to provide routing wires.

For conceptual reasons, two isolations between neighboring slices of bars are shown for each bar in FIG. 11. In other examples, each bar can extend as long as possible or as long as needed. Accordingly, the series of isolations along each bar can continue as many as possible. For example, the number of the isolations or transistor-pair slices can be dozens, hundreds, or thousands. Similarly, the number of bars over a substrate can be dozens, hundreds, or thousands.

Further, FIG. 11 shows two additional side views. The first side view corresponds to a first cross-section along a first cutline B-B′ cutting through the channels of three transistor-pair slices. The second side view corresponds to a second cross-section along a second cutline C-C′ cutting through the mandrels of three transistor-pair slices.

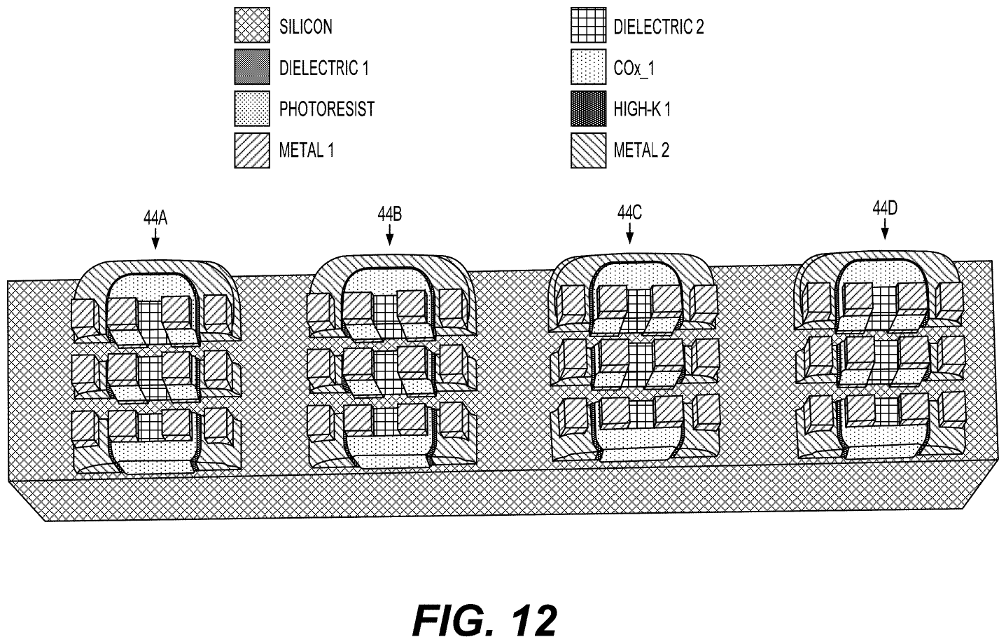

FIG. 12 shows a perspective view of the intermediate structure shown in FIG. 11 with the dielectric layer 31 being removed. It may appear that transistors of a transistor-pair slice 42 at the end of a bar are shortened. Four arrays 44a-44b of transistor pairs are formed.

As described herein, based on the fabrication process of FIGS. 1-11, a semiconductor device can be fabricated. In some embodiments, the semiconductor device can include a substrate (e.g., the substrate 10), a first wiring layer (for example, a wiring layer including the metal layer 16) over the substrate, and one or more first arrays (e.g., the arrays 44a-44d) of transistor pairs over the first wiring layer. Each first array of transistor pairs extends in a direction over the first wiring layer. Cross sections of each transistor pair of the same first array have a similar structure. Each transistor pair includes a mandrel having two opposite sidewalls that are perpendicular to the substrate and in parallel with the direction. Each transistor pair includes two transistors symmetrically disposed over the two opposite sidewalls of the mandrel. Each of the two transistors has a channel over one of the two opposite sidewalls of the mandrel, a gate dielectric over the channel, and a gate electrode over the gate dielectric.

In some embodiments, the semiconductor device can further include a second wiring layer (not shown) in parallel with the first wiring layer and above the first arrays of transistor pairs. Accordingly, the channel of each transistor in a transistor pair is in electrical connection with a first source/drain (S/D) contact structure provided in the first wiring layer. The channel of each transistor in a transistor pair also is in electrical connection with the second wiring layer through a second S/D contact structure (e.g., the contact structure 36).

In some embodiments, the semiconductor device can further include a transistor layer (not shown) stacked over the second wiring layer. The transistor layer includes one or more second arrays of transistor pairs. Transistor pairs in the second arrays each have a cross-section having a similar structure as that of the transistor pairs in the first arrays. Channels of the second array of transistors are in electrical connection with S/D contact structures provided in the second wiring layer. For example, the first wiring layer and the second wiring layer can each include one or more metal layers. In different examples, the first arrays of transistor pairs and the second arrays of transistor pairs extend in a same direction or in different directions.

In some embodiments, transistor pairs (or transistor-pair slices) in different transistor pair arrays may have different thicknesses (referring to a length along the direction in which the respective bar extends). In some embodiments, transistor pairs (or transistor-pair slices) in a same transistor pair array may have different thicknesses. In other words, the thickness of the transistor-pair slices can be adjusted depending on a particular application.

In some embodiments, instead of evenly placing the transistor arrays as shown in FIG. 11, the transistor arrays can be placed unevenly.

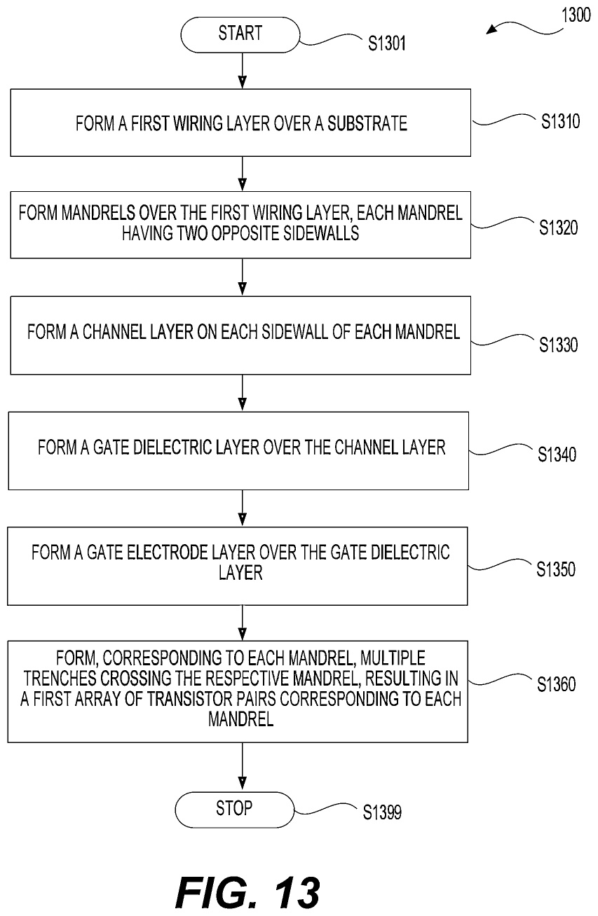

FIG. 13 shows a fabrication process 1300 according to embodiments of the disclosure. The fabrication process 1300 can start from S1301 and proceed to S1310.

At S1310, a first wiring layer is formed over a substrate. The first wiring layer can include one or multiple metal layers and interconnections between the multiple metal layers. FIGS. 1-2 show an example of forming a metal layer (the metal layer 16) of the first wiring layer.

At S1320, mandrels are formed over the first wiring layer. Each mandrel has two opposite sidewalls that are perpendicular to the substrate and extend in a direction. FIGS. 3-6 show an example of forming the mandrels (the mandrels 22).

At S1330, a channel layer is formed on each sidewall of each mandrel. The channel layer can be in electrical contact with the first wiring layer. FIGS. 5-6 show an example of forming the channel layer (the channel region 21).

At S1340, a gate dielectric layer is formed over the channel layer on each sidewall of each mandrel. FIGS. 7-8 show an example of forming the gate dielectric layer (the gate dielectric layer 27).

At S 1350, a gate electrode layer is formed over the gate dielectric layer formed over the channel layer on each sidewall of each mandrel. FIGS. 8-9 show an example of forming the gate electrode layer (the gate electrode layer 29).

At 51360, corresponding to each mandrel, multiple trenches are formed crossing the respective mandrel, the respective two channel layers on the two sidewalls of the respective mandrel, the respective two gate dielectric layers over the respective two channel layers, and the respective two gate electrode layers over the respective two gate dielectric layers, resulting in a first array of transistor pairs corresponding to each mandrel along the direction. FIGS. 10-11 show an example of forming the first array of transistor pairs. The process 1300 can proceed to 51399 and terminate at 51399.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A method, comprising:
forming a first wiring layer over a substrate;
forming mandrels over the first wiring layer, each mandrel having two opposite sidewalls that are perpendicular to the substrate and extend over the substrate;
forming a channel layer on each sidewall of each mandrel, the channel layer being in electrical contact with the first wiring layer;
forming a gate dielectric layer over the channel layer on each sidewall of each mandrel;
forming a gate electrode layer over the gate dielectric layer formed over the channel layer on each sidewall of each mandrel; and
forming, corresponding to each mandrel, multiple trenches, the multiple trenches crossing the respective mandrel, the channel layer on each sidewall of the respective mandrel, the gate dielectric layer over the channel layer on each sidewall of the respective mandrel, and the gate electrode layer over the gate dielectric layer formed over the channel layer on each sidewall of the respective mandrel, resulting in a first array of transistor pairs corresponding to each mandrel.

2. The method of claim 1, wherein the first wiring layer includes pairs of source/drain (S/D) contact structures, the S/D contact structures in each pair extending in a same direction as the mandrels,
each mandrel corresponds to a pair of S/D contact structures among the pairs of the S/D contact structures, each mandrel being positioned above a region extending between the two S/D contact structures of the respective pair of the S/D contact structures such that the two S/D contact structures are positioned at two sides of the respective mandrel, respectively, and
the channel layer on each sidewall of each mandrel is in electrical contact with a respective S/D contact structure of the respective pair of S/D contact structures in the first wiring layer.

3. The method of claim 2, wherein the multiple trenches corresponding to each mandrel cross the respective pair of S/D contact structures.

4. The method of claim 1, wherein each transistor pair has two transistors disposed on opposite sidewalls of a portion of the respective mandrel, the portion of the respective mandrel resulting from the multiple trenches crossing the respective mandrel.

5. The method of claim 4, wherein each transistor has a channel perpendicular to the substrate and a gate over the channel, the channel being a portion of the channel layer resulting from the multiple trenches crossing the respective mandrel, the gate being a combination of a portion of the gate dielectric layer and a portion of the gate electrode layer resulting from the multiple trenches crossing the respective mandrel.

6. The method of claim 5, further comprising:
forming a second wiring layer above the channels, the channels electrically connected to the first wiring layer providing a first S/D contact structure and the second wiring layer through a second S/D contact structure.

7. The method of claim 6, further comprising:
connecting the gate to the first wiring layer or the second wiring layer.

8. The method of claim 6, further comprising:
forming second arrays of transistor pairs over the second wiring layer in a similar way as forming the first arrays of transistor pairs over the first wiring layers such that the second arrays of transistor pairs are stacked over the first arrays of transistor pairs.

9. The method of claim 6, wherein the second wiring layer includes multiple metal layers.

10. The method of claim 6, wherein the channel is a nanosheet channel.

11. The method of claim 1, wherein the first wiring layer includes multiple metal layers.

12. The method of claim 1, wherein the transistor pairs are embedded in a low-k dielectric material.

13. The method of claim 1, wherein the channel includes one of a semiconductive oxide and a semiconductive 2D material.

14. The method of claim 1, further comprising:
after forming the channel layer on each sidewall of each mandrel, forming a dielectric layer over the first wiring layer, followed by the forming of the gate dielectric layer over the channel layer on each sidewall of each mandrel, such that the dielectric layer insulates the gate dielectric layer and the gate electrode layer from the first wiring layer under the dielectric layer.

15. The method of claim 1, wherein the channel includes one of the following materials: In2O3, SnO2, InGaZnO, ZnO, and SnO.

16. A semiconductor device, comprising:
a substrate;
a first wiring layer over the substrate; and
a first array of transistor pairs extending over the first wiring layer, cross sections of each transistor pair cutting through the first array, the cross sections of each transistor pair having a similar structure, each transistor pair including a mandrel having two opposite sidewalls that are perpendicular to the substrate and extending along a direction of the first array of transistor pairs, each transistor pair including two transistors symmetrically disposed over the two opposite sidewalls of the respective mandrel.

17. The semiconductor device of claim 16, wherein each of the two transistors has a channel over one of the two opposite sidewalls of the respective mandrel, a gate dielectric over the channel, and a gate electrode over the gate dielectric.

18. The semiconductor device of claim 17, further comprising a second wiring layer in parallel with the first wiring layer and above the first array of transistor pairs, the channel of each of the two transistors being in electrical connection with the first wiring layer providing a first source/drain (S/D) contact structure to the channel and with the second wiring layer through a second S/D contact structure.

19. The semiconductor device of claim 18, further comprising a transistor layer stacked over the second wiring layer, the transistor layer including a second array of transistor pairs each having a cross-section having a similar structure as that of each of the first array of transistor pairs, channels of the second array of transistors being in electrical connection with S/D contact structures provided in the second wiring layer.

20. The semiconductor device of claim 19, wherein the first wiring layer and the second wiring layer each include one or more metal layers, and
the first array of transistor pairs and the second array of transistor pairs extend in a same direction or different directions.
